(19) United States
(12) Patent Application Publication
(10) Pub. No.: US 2015/0194463 A1
(43) Pub. Date: Jul. 9, 2015

(54) METHOD OF MANUFACTURING SOLID-STATE IMAGE SENSOR

(71) Applicant: CANON KABUSHIKI KAISHA, Tokyo (JP)

(72) Inventors: Nobutaka Ukigaya, Yokohama-shi (JP); Koji Hara, Ichikawa-shi (JP)

(21) Appl. No.: 14/570,494

(22) Filed: Dec. 15, 2014

(30) Foreign Application Priority Data
Jan. 8, 2014 (JP) 2014-001954

(51) Int. Cl. H01L 27/146

(52) U.S. Cl. CPC H01L 27/14687

(57) ABSTRACT

A method of manufacturing an image sensor includes forming a resist film with a thickness of not less than 7 μm on a substrate having an effective region including a pixel array region and a peripheral region, and a non-effective region, forming a resist pattern including first, second and third openings from the resist film, and implanting ions into the pixel array region through the first, second and third openings. The first opening is arranged in the effective region to implant the ions into the pixel array region, the third opening is arranged in the non-effective region, and at least a part of the second opening is arranged between the first opening and the third opening, and a minimum curvature radius of an edge of the second opening is larger than that of the third opening.

### BACKGROUND OF THE INVENTION

1. Field of the Invention

The present invention relates to a method of manufacturing a solid-state image sensor.

2. Description of the Related Art

As one approach for increasing the sensitivity of a solid-state image sensor, there is an approach of forming a depletion layer up to a deep position in a semiconductor substrate. In this approach, it is necessary to implant ions into the semiconductor substrate using an energy of over 1 MeV. Furthermore, in order to implant the ions selectively into a limited region of the semiconductor substrate, an ion implantation mask must have a sufficient ion blocking ability against ion implantation with high energy.

Japanese Patent Laid-Open No. 2002-217123 describes a method of forming a first inorganic film, a silicon layer, and a second inorganic film in order on the surface of a silicon substrate, patterning the second inorganic film, and patterning the silicon layer using the patterned second inorganic film as a mask. In this method, ions are implanted into the silicon substrate via the first inorganic film using the patterned silicon layer as a mask. In this method, however, the process for forming an ion implantation mask is complex, resulting in a decrease in manufacturing efficiency.

### SUMMARY OF THE INVENTION

The present invention provides a technique advantageous in simplifying a process.

One of aspects of the present invention provides a method of manufacturing a solid-state image sensor, comprising steps of: forming a resist film with a thickness of not less than 7 μm on a semiconductor substrate where an effective region which includes a pixel array region including a plurality of pixels and a peripheral region arranged outside the pixel array region, and a non-effective region which is arranged adjacent to the effective region are defined; forming a resist pattern including a first opening, a second opening, and a third opening by performing a photolithography process for the resist film; and implanting ions into the pixel array region on the semiconductor substrate through the first opening, the second opening, and the third opening, wherein the first opening is arranged in the effective region to implant the ions into the pixel array region, the third opening is arranged in the non-effective region, and at least a part of the second opening is arranged between the first opening and the third opening, and shapes of the second opening and the third opening in a section parallel to a surface of the semiconductor substrate are formed such that a minimum curvature radius of an edge of the second opening becomes larger than that of the third opening.

Further features of the present invention will become apparent from the following description of exemplary embodiments with reference to the attached drawings.

### BRIEF DESCRIPTION OF THE DRAWINGS

FIG. 1A is a view showing a semiconductor substrate on which a plurality of solid-state image sensors being manufactured is arrayed;

FIG. 1B is a schematic view showing one solid-state image sensor being manufactured and its periphery;

FIG. 2A is a schematic plan view showing a second opening and a third opening;

FIG. 2B is a schematic sectional view showing the second opening and the third opening;

FIGS. 3A and 3B are schematic views each showing the section of the solid-state image sensor being manufactured;

FIGS. 4A and 4B are schematic views each showing the section of the solid-state image sensor being manufactured;

FIGS. 5A and 5B are schematic views each showing the section of the solid-state image sensor being manufactured;

FIGS. 6A and 6B are schematic views each showing the section of the solid-state image sensor being manufactured;

FIGS. 7A and 7B are schematic views each showing the section of the solid-state image sensor being manufactured;

FIGS. 8A and 8B are schematic views each showing the section of the solid-state image sensor being manufactured;

FIGS. 9A and 9B are schematic views each showing the section of the solid-state image sensor being manufactured;

FIG. 10 is a schematic view showing the section of the solid-state image sensor being manufactured;

FIG. 11 is a view showing a modification of a resist pattern;

FIG. 12 is a view showing a modification of the resist pattern;

FIG. 13 is a view showing a modification of the resist pattern; and

FIGS. 14A and 14B are views for explaining a crack problem.

### DESCRIPTION OF THE EMBODIMENTS

An exemplary embodiment of the present invention will be described below with reference to the accompanying drawings.

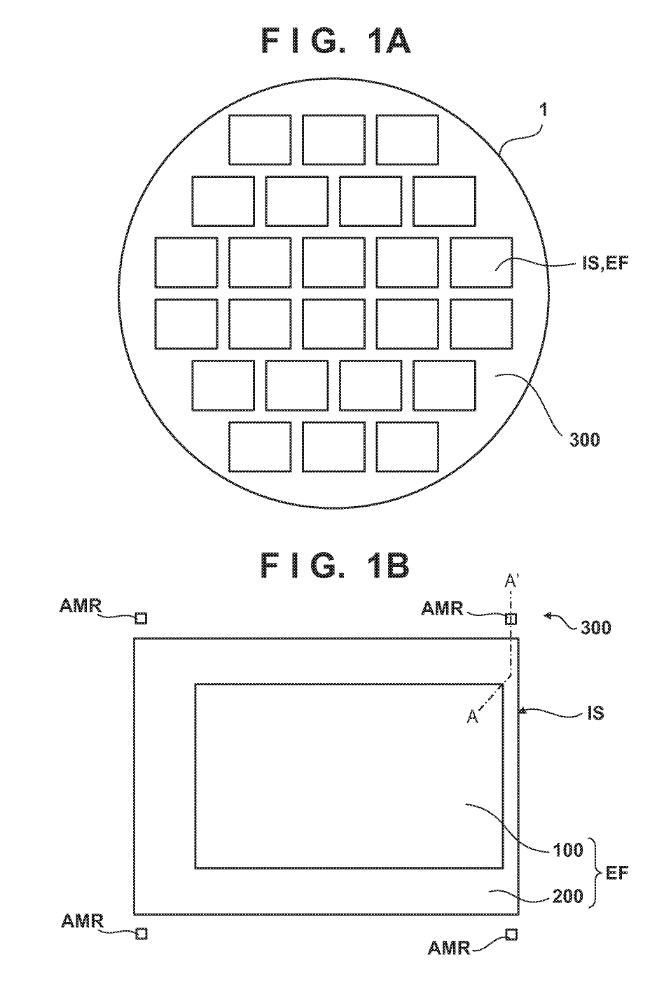

FIG. 1A schematically shows a semiconductor substrate 1 on which a plurality of solid-state image sensors IS being manufactured are arrayed. FIG. 1B schematically shows one solid-state image sensor IS being manufactured and its periphery. Effective regions EF and a non-effective region 300 arranged adjacent to the effective regions EF are defined on the semiconductor substrate 1. Each effective region EF includes a pixel array region 100 including a plurality of pixels and a peripheral region 200 arranged outside the pixel array region 100. In another aspect, each solid-state image sensor IS is formed in the effective region EF, and includes the pixel array region 100 and the peripheral region 200.

When each solid-state image sensor IS is formed as a MOS image sensor, each pixel can include, for example, a photoelectric conversion unit, a transfer transistor, a charge-voltage conversion unit, a reset unit, an output unit, and a selection unit. However, each solid-stage image sensor IS may be formed as another form of image sensor such as a CCD image sensor. The peripheral region 200 can include, for example, a vertical scanning circuit, a constant current source block, a column amplifier block, a holding capacitor block, a horizontal scanning circuit, and an output amplifier block.

The non-effective region 300 includes alignment mark regions AMR. In a plurality of photolithography processes for manufacturing the solid-state image sensors IS, alignment marks are formed in the alignment mark regions AMR. The non-effective region 300 can be, for example, a scribe line for isolating the plurality of solid-state image sensors IS from each other.

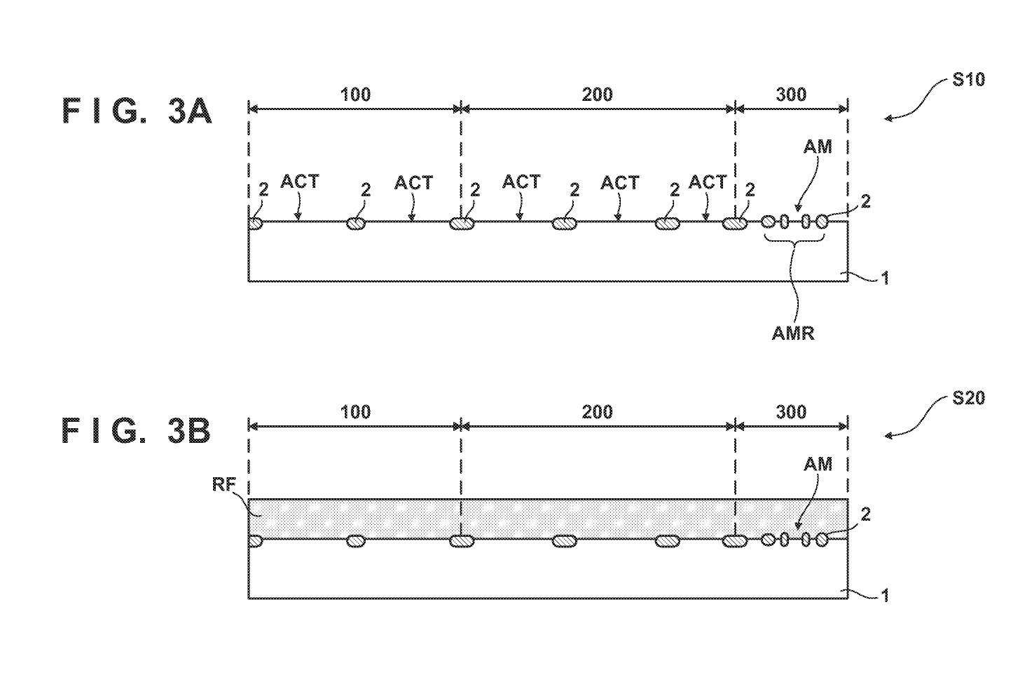

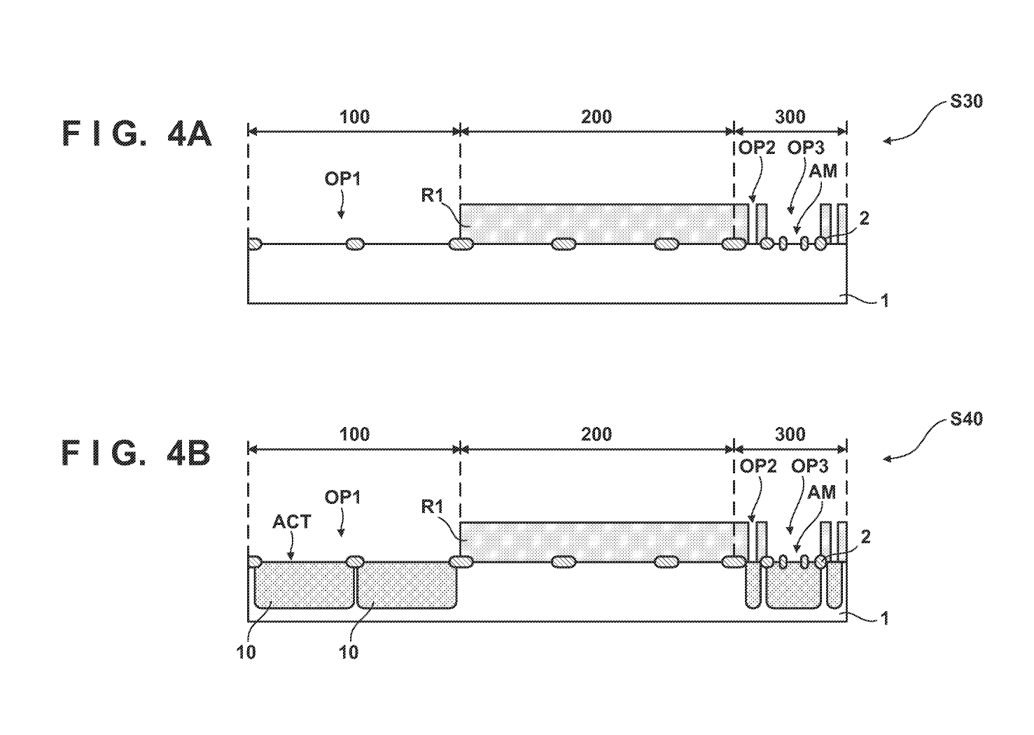

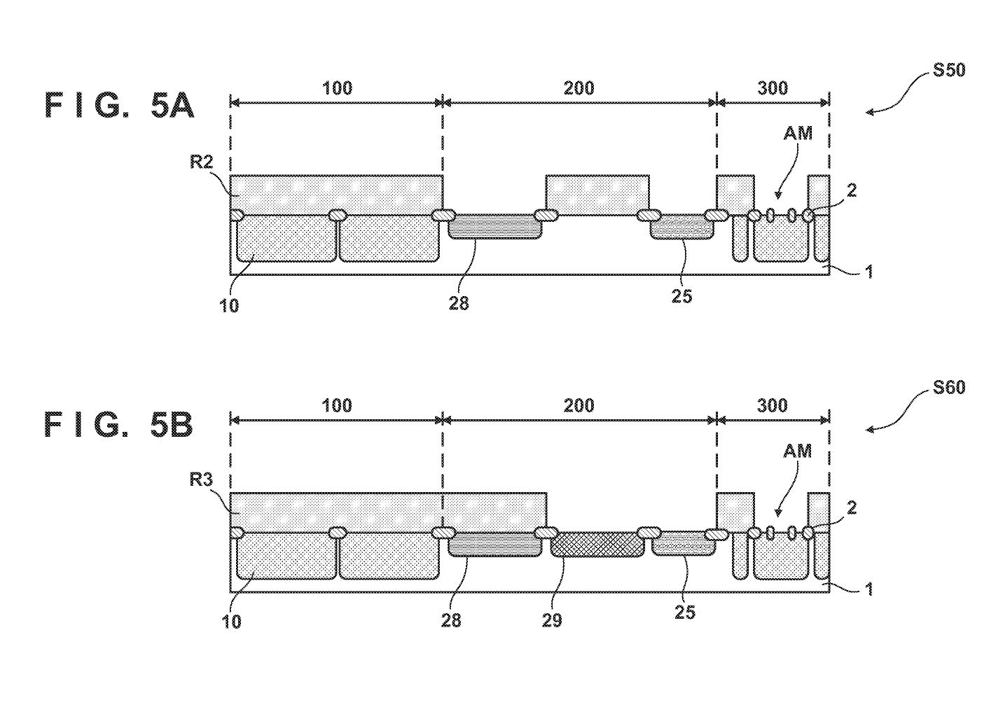

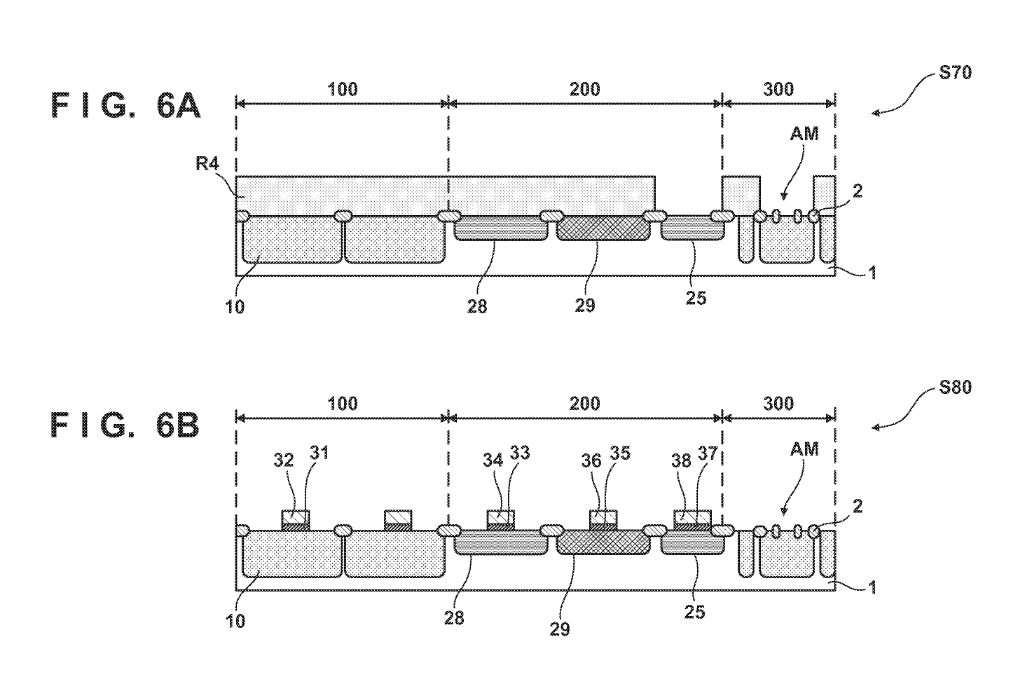

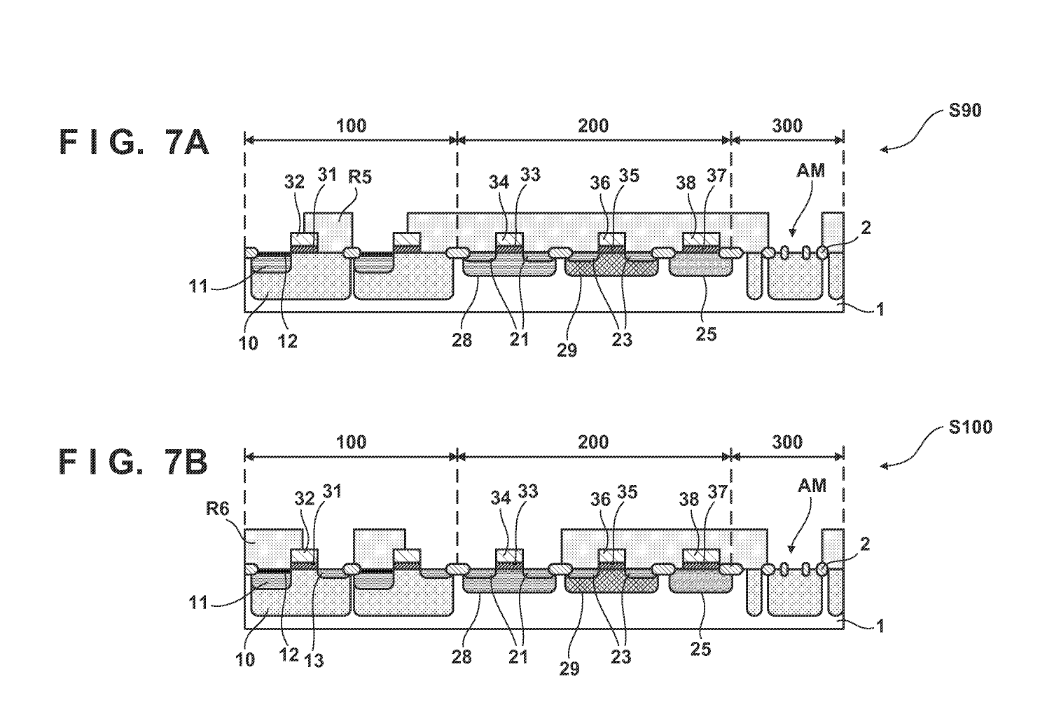

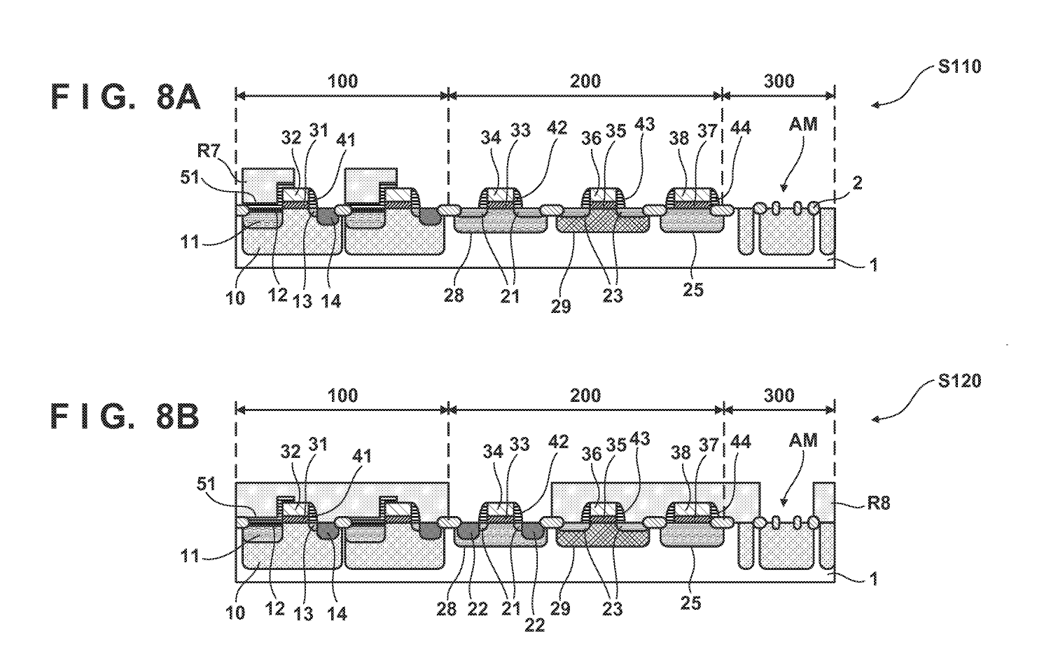

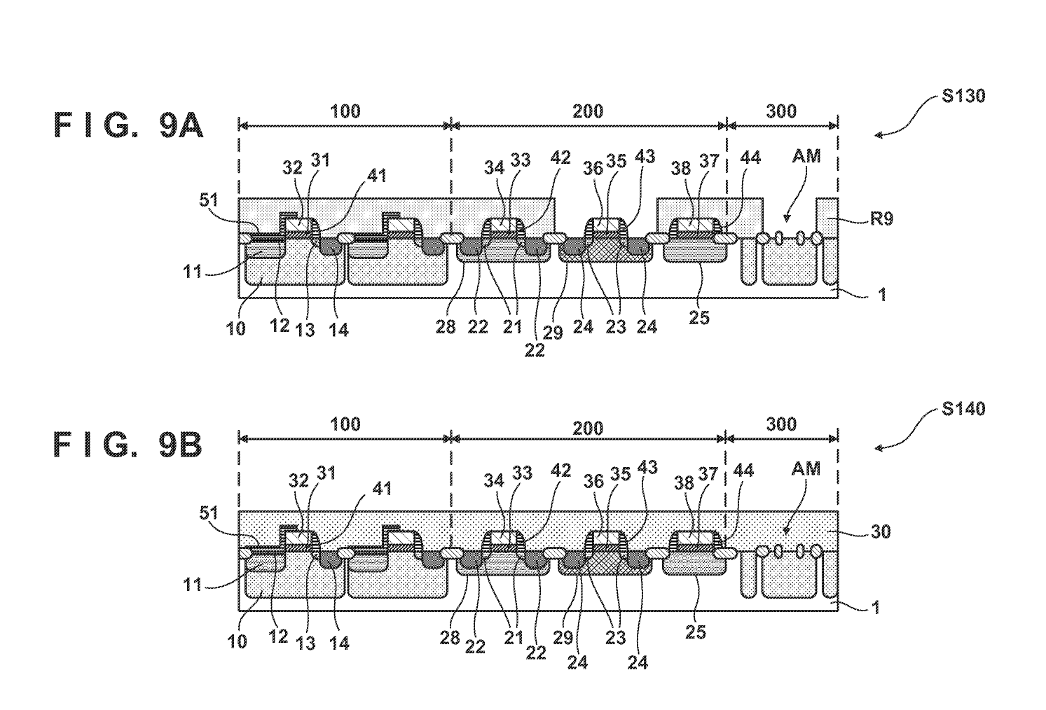

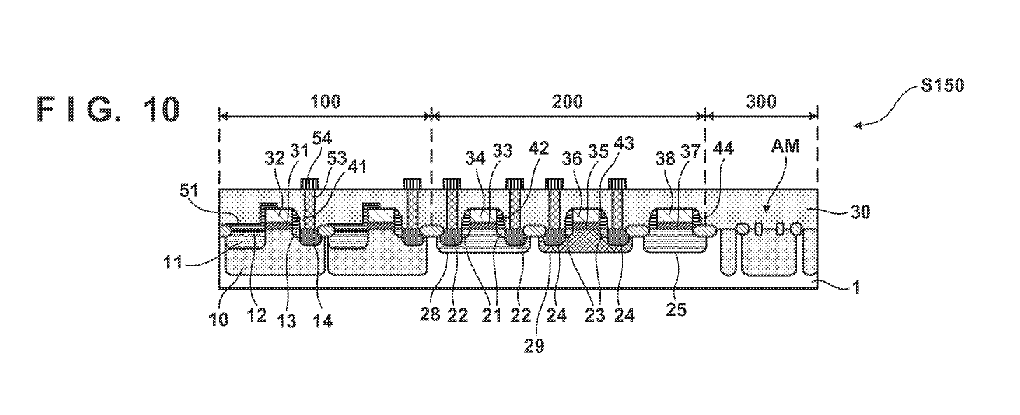

FIGS. 3A to 10 schematically show the section of the solid-state image sensor IS being manufactured, taken along an A-A′ line in FIG. 1B. A method of manufacturing the solid-state image sensor IS will exemplarily be described below with reference to FIGS. 3A to 10. The semiconductor substrate 1 includes active regions ACT and element isolation regions 2. Each active region ACT is defined in a region where no element isolation region 2 exists. That is, the active region ACT and the element isolation region 2 are complementary to each other. The pixel array region 100 includes the active region ACT and the element isolation region 2, and the peripheral region 200 also includes the active region ACT and the element isolation region 2. Furthermore, the non-effective region 300 can also include the active region ACT and the element isolation region 2. The element isolation region 2 can be, for example, a LOCOS element isolation region or an STI element isolation region. The element isolation region 2 has a function of isolating a plurality of semiconductor regions from each other. The semiconductor regions isolated from each other can be, for example, the semiconductor region where the photoelectric conversion unit is formed, or the semiconductor region where the source and drain of a transistor, or a capacitor is formed.

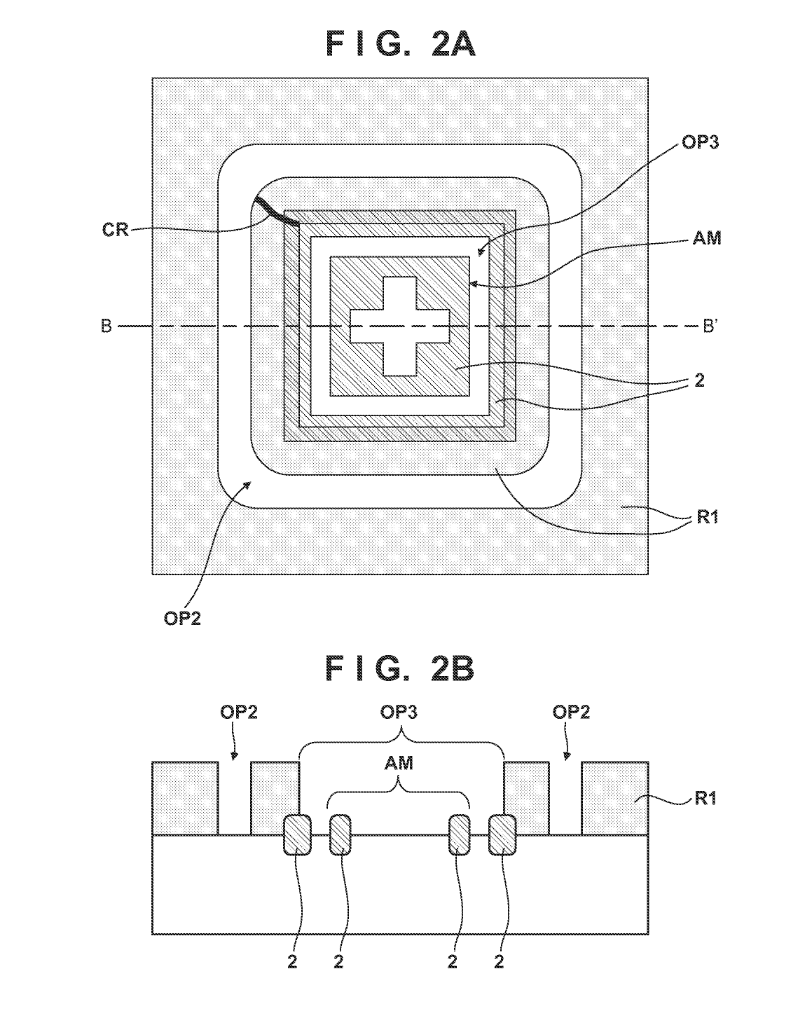

In step S10, the semiconductor substrate 1 including the active region ACT and the element isolation region 2 is prepared. In an example shown in FIGS. 2A and 2B, each of the pixel array region 100, the peripheral region 200, and the non-effective region 300 includes the active region ACT and the element isolation region 2. The element isolation region 2 forms an alignment mark AM in the alignment mark region AMR of the non-effective region 300.

In steps S20 and S30, a resist pattern R1 for implanting ions with, for example, an ultrahigh energy of 6 MeV is formed. First, in step S20, a resist film RF is formed on the semiconductor substrate 1 including the active region ACT and the element isolation region 2. The resist film RF can typically be formed by coating the semiconductor substrate 1 with a resist material by spin coating. The resist film RF can have a thickness of 7 μm or more.

In step S30, the resist pattern R1 having a first opening OP1, a second opening OP2, and a third opening OP3 is formed by performing the photolithography process for the resist film RF. FIGS. 2A and 2B schematically show the second opening OP2 and the third opening OP3. FIG. 2A is a plan view and FIG. 2B is a sectional view taken along a B-B′ line in FIG. 2A.

The first opening OP1 is arranged in the effective region EF to implant ions into the pixel array region 100. The third opening OP3 is arranged in the non-effective region 300. At least a part of the second opening OP2 is arranged between the first opening OP1 and the third opening OP3. Although the second opening OP2 is typically arranged in the non-effective region 300, it may be arranged in the effective region EF. The shapes of the second opening OP2 and the third opening OP3 in a section parallel to the surface of the semiconductor substrate 1 are determined and formed such that the minimum curvature radius of the edge of the second opening OP2 becomes larger than that of the third opening OP3. This is effective in reducing the possibility of crack occurrence in the second opening OP2. As shown in FIG. 2A, when the edge of the third opening OP3 has right-angle corners in the shapes of the second opening OP2 and the third opening OP3 in the section parallel to the surface of the semiconductor substrate 1, the edge of the second opening OP2 preferably has an obtuse angle or roundish shape rather than a right angle. The shape in the section of the second opening OP2 can be defined by the edge on the side of the first opening OP1 and the shape in the section of the third opening OP3 can be defined by the edge on the side of the second opening OP2.

In one example, ZR8800 (manufactured by Tokyo Ohka) is used as a material for the resist film RF, and the thickness of the resist film RF is set to 9 μm. A lithography step includes coating, exposure, and development of the resist film, and burning (post-bake). Burning can be performed, for example, at 120° C. for 120 sec. Burning can expand the dimensions of the first opening OP1, the second opening OP2, and the third opening OP3.

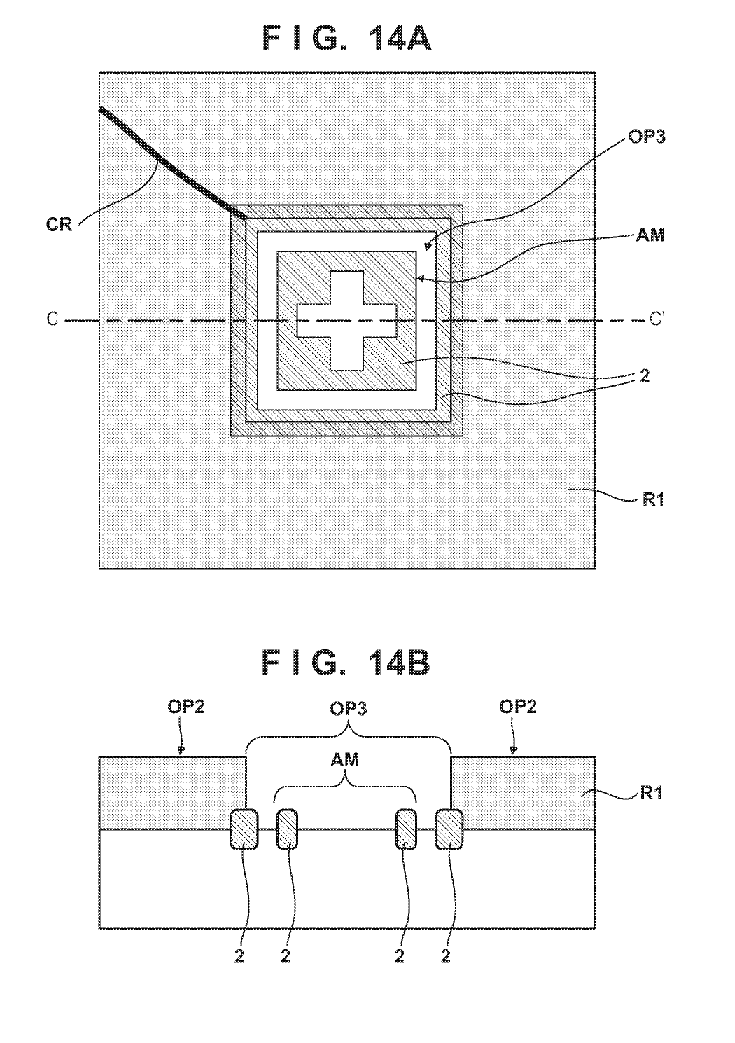

A problem founded by the present inventor will be described with reference to FIGS. 14A and 14B. If the thickness of the resist film RF is 7 μm or more, a crack CR extending from, for example, the corner portion of the third opening OP3 is formed in burning the resist pattern R1 after development unless the second opening OP2 is provided between the first opening OP1 and the third opening OP3. A phenomenon in which this crack CR reaches the first opening OP1 frequently occurs. The crack CR may also be produced under a low-pressure environment for implanting ions into the semiconductor substrate 1 using the resist pattern R1. The first opening OP1 can be used to implant ions into the pixel array region 100. Therefore, if the crack CR reaches the first opening OP1, the ions are also implanted into a portion in the pixel array region 100 where ion implantation should not be performed. This may result in a failure.

The present inventor has found that the crack CR extending from the third opening OP3 can be terminated in the second opening OP2 as schematically shown in FIGS. 2A and 2B by forming the second opening OP2 between the first opening OP1 and the third opening OP3. It is effective to determine the shapes of the second opening OP2 and the third opening OP3 in the section parallel to the surface of the semiconductor substrate 1 such that the minimum curvature radius of the edge of the second opening OP2 becomes larger than that of the third opening OP3.

While the maximum dimension of the first opening OP1 for implanting ions into the pixel array region 100 is larger than that of the second opening OP2 for terminating the crack CR, the maximum dimension of the second opening OP2 is larger than that of the third opening OP3 including a formation region for the alignment mark AM. The second opening OP2 can be arranged to surround the third opening OP3, preferably over its entire circumference.

A side face which forms the third opening OP3 in the resist pattern R1 can be arranged on the element isolation region 2. A side face which forms the second opening OP2 in the resist pattern R1 can be arranged on the active region ACT. A side face which forms the first opening OP1 in the resist pattern R1 can be arranged on the element isolation region 2.

By providing the second opening OP2, the crack CR is less likely to reach the first opening OP1 while keeping a thick resist pattern. This eliminates a need to form a film (such as a silicon film or a silicon nitride film) other than the resist film as a mask. Therefore, it is possible to simplify a process for forming an ion implantation mask.

In step S40, ions (boron (B)) are implanted into the semiconductor substrate 1 with, for example, an ultrahigh energy of 6 MeV through the first opening OP1 of the resist pattern R1. At this time, the ions are also implanted into the semiconductor substrate 1 through the second opening OP2 and the third opening OP3. In examples shown in FIGS. 3A to 10, the resist pattern R1 has one common opening OP1 to the plurality of pixels in one pixel array region 100. When the semiconductor substrate 1 includes N regions of the solid-state image sensors IS, the resist pattern R1 has N openings OP1 for N pixel array regions 100. By performing step S40, a well (first semiconductor region) 10 is formed in the pixel array region 100.

In steps S50, S60, and S70, resist patterns R2, R3, and R4 are formed, and ions are implanted into the semiconductor substrate 1 through the resist patterns R2, R3, and R4. This forms diffusion layers (the source and drain) 28 of each of an NMOS transistor and a PMOS transistor in the peripheral region 200, and a diffusion layer (lower electrode) 25 for the holding capacitor of the holding capacitor block in the peripheral region. The thickness of each of the resist patterns R2, R3, and R4 is, for example, about 1 μm, and no crack is produced.

In step S80, an insulating film and a polysilicon film are formed in order on the semiconductor substrate 1, and patterned. By doing so, a gate structure including a gate insulating film 31 and a gate electrode 32 is formed in the pixel array region 100 (the gate structure of the transfer transistor is shown). In the peripheral region 200, while a gate electrode including a gate insulating film 33 and a gate electrode 34 is formed in the region of the NMOS transistor, a gate electrode including a gate insulating film 35 and a gate electrode 36 is formed in the region of the PMOS transistor. Furthermore, a structure including an insulating film 37 and an upper electrode 38 is formed in the region of the holding capacitor in the peripheral region 200.

In step S90, a resist pattern (second resist pattern) R5 having a plurality of openings corresponding to the respective charge accumulation regions 11 of the plurality of pixels is formed. An impurity (here, arsenic (As)) of the first conductivity type (here, an n type) is implanted into the semiconductor substrate 1 using the resist pattern R5 and the gate electrode 32 as masks. This forms the charge accumulation region (second semiconductor region) 11 made of a semiconductor region of the first conductivity type. The maximum depth of the charge accumulation region 11 is smaller than that of the well 10. In step S90, an impurity (here, boron (B)) of the second conductivity type (here, a p type) is implanted in the vicinity of the surface of the semiconductor substrate 1 using the resist pattern R5 and the gate electrode 32 as masks. This forms a protective region 12 on the charge accumulation region 11. The protective region 12 of the second conductivity type, the charge accumulation region 11 of the first conductivity type, and the well 10 of the second conductivity type form a buried photoelectric conversion unit.

In step S100, a resist pattern R6 is formed, and the impurity of the first conductivity type is implanted into the semiconductor substrate 1 at a low concentration using the resist pattern R6 and the gate electrodes 32 and 34 as masks. This forms a lightly doped region 13 of the charge-voltage conversion unit (floating diffusion) in the pixel array region 100 and an LDD region 21 of the NMOS transistor in the peripheral region 200.

In step S110, a two-layer insulating film is formed to cover the gate electrodes 32, 34, and 36 and the upper electrode 38. Out of the two-layer insulating film, the first-layer insulating film is formed by, for example, a silicon nitride film (SiN). The first-layer insulating film preferably has a film thickness of 40 nm to 55 nm, considering that it is made to function as an antireflection film which prevents light reflection on the light receiving surface of the photoelectric conversion unit (protective region 12). Then, the second-layer insulating film is formed to cover the first-layer insulating film. The second insulating film can be formed by, for example, a silicon oxide film (SiO₂).

In step S110, a resist pattern R7 covering the protective region 12 is further formed on the two-layer insulating film. Then, etching is performed using the resist pattern R7 as a mask. This forms a side wall spacer 41 on the side faces of the gate electrode 32 and the gate insulating film 31 on the side of the charge-voltage conversion unit as well as an insulating film 51 which covers the protective region 12 and the side faces of the gate electrode 32 and the gate insulating film 31 on the side of the protective region 12. Moreover, side wall spacers 42, 43, and 44 are also formed on the side face of the gate electrode 34 and the gate insulating film 33, the side face of the gate electrode 36 and the gate insulating film 35, and the side face of the upper electrode 38 and the insulating film 37, respectively. After that, the resist pattern R7 is removed.

In step S120, a resist pattern R8 having an opening in the region of the NMOS transistor is formed, and ions of the first conductivity type are implanted into the semiconductor substrate 1 at a high concentration using the resist pattern R8, the gate electrode 34, and the side wall spacer 42 as masks. This forms the source and drain 22 of the NMOS transistor.

In step S130, a resist pattern R9 having an opening in the region of the PMOS transistor is formed, and ions of the second conductivity type are implanted into the semiconductor substrate 1 at the high concentration using the resist pattern R9, the gate electrode 36, and the side wall spacer 43 as masks. This forms the source and drain 24 of the PMOS transistor.

In step S140, an interlayer insulating film 30 is formed on the semiconductor substrate 1. In step S150, a contact hole is formed in the interlayer insulating film 30, a contact plug 53 is formed in that contact hole, and an interconnection pattern 54 is further formed on the interlayer insulating film 30. Although not shown below, the interlayer insulating film and the interconnection pattern are further stacked, and then a color filter, a microlens, and the like are formed on them.

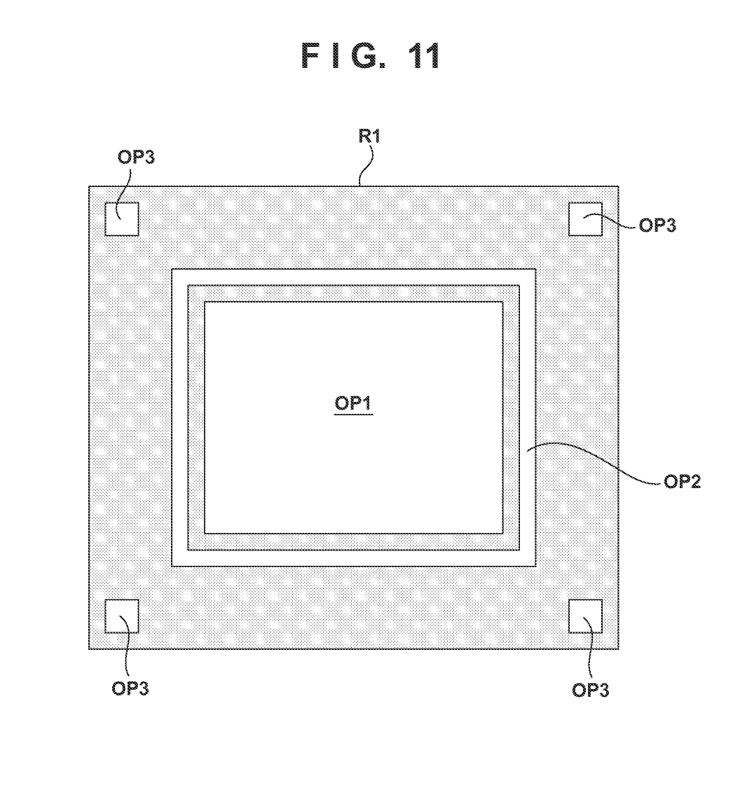

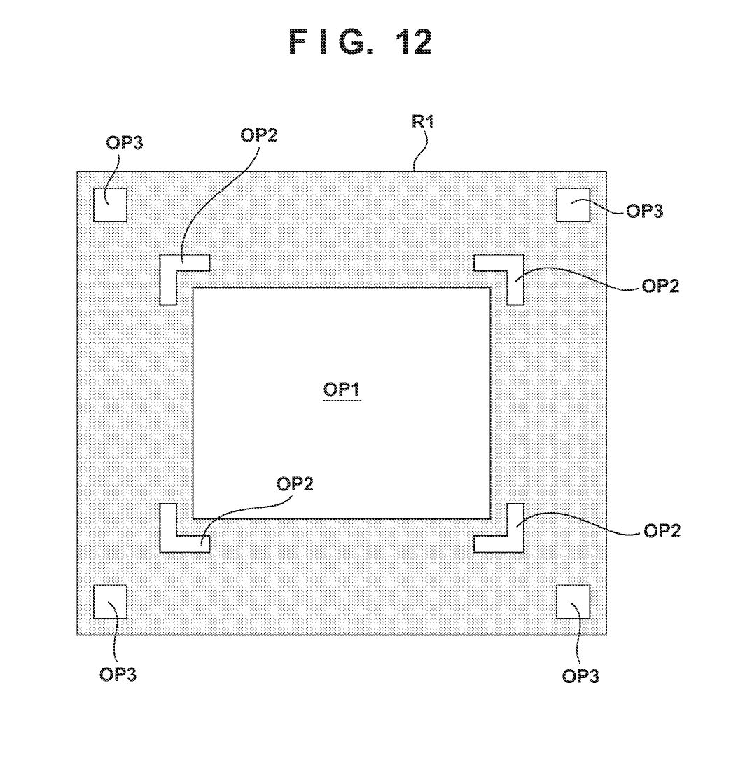

FIG. 11 shows a modification of the second opening OP2. In the example shown in FIG. 11, the second opening OP2 is arranged to surround an entire circumference of the first opening OP1. FIG. 12 shows another modification of the second opening OP2. In the example shown in FIG. 12, the second opening OP2 is arranged to partially surround the first opening OP1. In another aspect, at least a part of the second opening OP2 is arranged between the third opening OP3 and the corner portion of the first opening OP1.

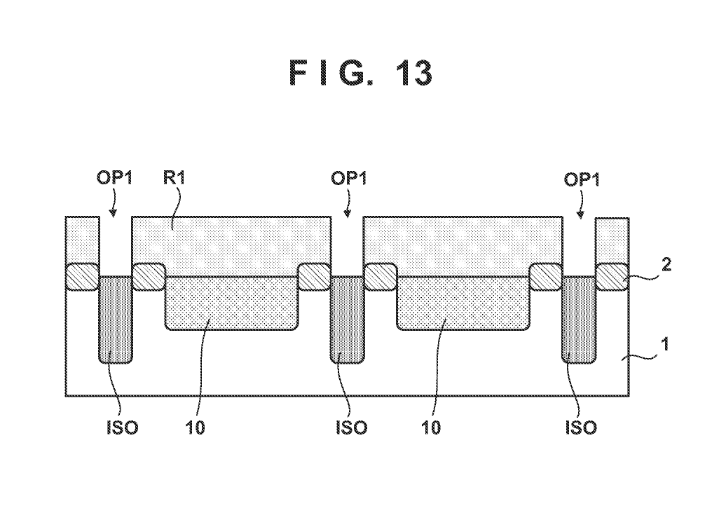

FIG. 13 shows a modification of the first opening OP1. FIG. 13 illustrates the resist pattern R1 having the plurality of openings OP1 for one pixel array region 100. Such resist pattern R1 is used to implant ions into regions isolated from each other within one pixel array region 100 at, for example, an ultrahigh energy of 6 MeV. The plurality of openings OP1 can be used to form semiconductor regions ISO which isolate the plurality of pixels forming the pixel array region 100 from each other.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-001954, filed Jan. 8, 2014, which is hereby incorporated by reference herein in its entirety.

What is claimed is:

1. A method of manufacturing a solid-state image sensor, comprising steps of:
forming a resist film with a thickness of not less than 7 μm on a semiconductor substrate where an effective region which includes a pixel array region including a plurality of pixels and a peripheral region arranged outside the pixel array region, and a non-effective region which is arranged adjacent to the effective region are defined;
forming a resist pattern including a first opening, a second opening, and a third opening by performing a photolithography process for the resist film; and
implanting ions into the pixel array region on the semiconductor substrate through the first opening, the second opening, and the third opening,
wherein the first opening is arranged in the effective region to implant the ions into the pixel array region, the third opening is arranged in the non-effective region, and at least a part of the second opening is arranged between the first opening and the third opening, and
shapes of the second opening and the third opening in a section parallel to a surface of the semiconductor substrate are formed such that a minimum curvature radius of an edge of the second opening becomes larger than that of the third opening.

2. The method according to claim 1, wherein a maximum dimension of the first opening is larger than that of the second opening, and the maximum dimension of the second opening is larger than that of the third opening.

3. The method according to claim 1, wherein the second opening is arranged to surround the third opening.

4. The method according to claim 1, wherein the second opening is arranged to surround an entire circumference of the third opening.

5. The method according to claim 1, wherein the second opening is arranged to surround the first opening.

6. The method according to claim 1, wherein the second opening is arranged to surround an entire circumference of the first opening.

7. The method according to claim 1, wherein the at least part of the second opening is arranged between the third opening and a corner portion of the first opening.

8. The method according to claim 1, wherein a side face which forms the third opening in the resist pattern is arranged on an element isolation region formed on the semiconductor substrate.

9. The method according to claim 1, wherein a side face which forms the second opening in the resist pattern is arranged on an active region on the semiconductor substrate.

10. The method according to claim 1, wherein a side face which forms the first opening in the resist pattern is arranged on the element isolation region formed on the semiconductor substrate.

11. The method according to claim 1, wherein the first opening is one common opening to the plurality of pixels which form the pixel array region.

12. The method according to claim 1, wherein the resist pattern includes the plurality of the openings.

13. The method according to claim 12, wherein in the implanting the ions, a semiconductor region which isolates the plurality of pixels which form the pixel array region from each other is formed.

14. A method of manufacturing a solid-state image sensor, comprising steps of:
forming a resist film with a thickness of not less than 7 μm on a semiconductor substrate where an effective region which includes a pixel array region including a plurality of pixels and a peripheral region arranged outside the pixel array region, and a non-effective region which is arranged adjacent to the effective region are defined;
forming a resist pattern including a first opening, a second opening, and a third opening by performing a photolithography process for the resist film; and
implanting ions into the pixel array region on the semiconductor substrate through the openings, wherein the first opening is arranged in the effective region to implant the ions into the pixel array region, the third opening is arranged in the non-effective region, and the second opening is arranged between the first opening and the third opening, and
a side face which forms the third opening in the resist pattern is arranged on an element isolation region formed on the semiconductor substrate.

15. The method according to claim 14, wherein a side face which forms the second opening in the resist pattern is arranged on an active region on the semiconductor substrate.

16. The method according to claim 14, wherein a side face which forms the first opening in the resist pattern is arranged on the element isolation region formed on the semiconductor substrate.
